(19) United States
(12) Patent Application Publication
(10) Pub. No.: US 2024/0112906 A1
(43) Pub. Date: Apr. 4, 2024

(54) MANUFACTURING METHOD OF INSULATION FILM

(71) Applicant: ABIT TECHNOLOGIES CO., LTD, Tokyo (JP)

(72) Inventor: Kiyokazu NAKAGAWA, Tokyo (JP)

(73) Assignee: ABIT TECHNOLOGIES CO., LTD, Tokyo (JP)

(21) Appl. No.: 18/266,110

(22) PCT Filed: Dec. 2, 2021
(86) PCT No.: PCT/JP2021/044334

§ 371 Date: Jun. 8, 2023

(30) Foreign Application Priority Data
Dec. 9, 2020 (JP) 2020-204626

(51) Int. Cl. H01L 21/02

(52) U.S. Cl. CPC H01L 21/02282; H01L 21/02216; H01L 21/02222; H01L 21/02252; H01L 21/02164

(57) ABSTRACT

An object is to provide a manufacturing method of an insulation film in which no heating at high temperature is necessary. The manufacturing method of the insulation film includes a deposition process, a heating process and an exposure process. In the deposition process, a material is deposited on a substrate 11. In the heating process, the substrate 11 is heated at a temperature equal to or higher than 85° C. to equal to or lower than 450° C. In the exposure process, by irradiating a surface SA2 of a deposition material layer 12 on the substrate 11 with a plasma 82 containing hydrogen radicals, hydrogen is made to diffuse into the structure of the deposition material layer 12 and bind with components of the deposition material layer 12. A product of an irradiation time and a density of the radicals formed by the plasma 82 is equal to or higher than 25×10¹⁴ min·pcs/cm³.

### TECHNICAL FIELD

The present invention relates to a manufacturing method of an insulation film with good insulation characteristics, and more particularly, relates to a manufacturing method of an insulation film that does not require any high temperature annealing process.

### BACKGROUND

A silicon oxide film may be formed as an insulation film on a substrate or a substrate with a semiconductor device pattern. The silicon oxide film is often formed by a plasma-enhanced chemical vapor deposition (CVD) with a silane gas (SiH₄) or a tetraethoxysilane (TEOS) as a source thereof, or formed by coating the substrate with a spin on glass (SOG) and annealing the same.

Forming of the silicon oxide film by a plasma CVD is a method of forming a plasma of monosilane gas or disilane gas and oxygen by electromagnetic wave radiation in a reaction chamber, and, as a result, depositing SiO₂ on a substrate kept at around 400° C. A dielectric breakdown electric field of a silicon oxide film formed by this method tends to be low as hydrogen is included in monosilane gas and disilane gas.

In addition, in the forming of a silicon oxide film by the plasma CVD, a flattening process at a temperature around 900° C. may be required in order to keep concave and convex shapes of the substrate.

On the other hand, when SOG is used, a heating at a high temperature equal to or higher than 800° C. is required in order to obtain a dense silicon oxide film.

In any one of these methods, as a heating at a high temperature is required, a deterioration in characteristics of a gate oxide film or the like formed on the substrate before forming the silicon oxide film may be led.

It should be noted that Patent Literature 1 discloses techniques of annealing at a relatively low temperature after coating with SOG and then treating a surface with accelerated high-density plasma to physically condense a film formed of SOG.

### CITED REFERENCES

### Patent Literatures

[Patent Literature 1] Japanese Patent Application Publication 2015-521375

### SUMMARY

### Problem to be Sold by the Invention

By forming a silicon oxide film by use of SOG according to the techniques disclosed in the above-mentioned Patent Literature 1, it becomes possible to avoid a deterioration in characteristics of a gate oxide film or the like formed on a substrate before forming a silicon oxide film.

However, according to the techniques disclosed in the Patent Literature 1, agate oxide film or the like formed on a substrate before forming a silicon oxide film may be electrostatically destroyed by electric charge brought by plasma to the silicon oxide film.

In addition, according to the techniques disclosed in the Patent Literature 1, as ion species bombardment is used to densify the film formed of SOG, only a surface of the film formed of SOG, specifically only a surface layer from the surface to around 50 nm depth, is limitedly condensed. Therefore, such techniques are not suitable for a use that requires an insulation film with a thickness of 100 nm or more for example. It should be noted that in case of densifying a film by use of ion species bombardment, it is necessary to increase ion acceleration energy to thicken the insulation film, and as a result, it is not easy to increase density of an obtained dielectric layer while increasing insulation characteristics thereof.

The present invention has been made in view of such circumstances and has an objective of providing a manufacturing method of an insulation layer which requires no heating at a high temperature, and the like.

### Means for Solving the Problems

In an aspect of the present invention, a manufacturing method of an insulation film is provided, the method including: a process of depositing a film deposition material on a substrate to form a deposition material layer; a process of heating the film deposition material on the substrate at 85° C. or more to 450° C. or less; and a process of irradiating a surface of the deposition material layer on the substrate with a plasma containing hydrogen radicals to make hydrogen diffuse into a structure of the deposition material layer and bind the hydrogen to a component of the deposition material layer, and a product of irradiation time and a density of the radicals formed by the plasma is equal to or higher than 25×10¹⁴ min·pcs/cm³.

According to the above-mentioned method, by making the hydrogen diffuse while basically maintaining chemical skeleton structure of the film deposition material in the deposition material layer, the hydrogen penetrated inside by diffusion can be made react with a component of the deposition material layer to make hydrogen molecules be released. As the hydrogen molecules thus generated are expelled outside the deposition material layer, the hydrogen concentration in the film can be made extremely low, and the insulation characteristics of the deposition material layer can be improved. At that time, as no heating at a high temperature is required, the insulation characteristics of the insulation film can be improved without deteriorating the characteristics of the substrate before the forming of the insulation film corresponding to the deposition material layer after plasma irradiation treatment or the device portion formed thereon. Furthermore, if the product of the irradiation time and the density of the radicals contained in the plasma is equal to or higher than 25×10¹⁴ min·pcs/cm³, the hydrogen can be diffused deeply with a sufficient density into the structure of the deposition material layer, and an insulation film with high insulation characteristics can be obtained.

According to a detailed aspect of the present invention, the radicals are provided to the surface of the deposition material layer by a forming of the plasma under a pressure equal to or higher than 5 Pa to equal to or lower than 50 Pa. By setting the plasma to 5 Pa or higher, a density of the plasma in contact with the deposition material layer is increased, potential difference between the plasma and the deposition material layer can be easily set to 10V or lower, and it can prevent plasma particles from being injected into the deposition material layer, disturbing the structure of the deposition material layer, and decreasing the density of the deposition material layer. On the other hand, by setting the plasma to 50 Pa or less, a mean free path of the radicals can be kept relatively long, and the generated radicals can be effectively used to reach the deposition material layer.

According to yet another aspect of the present invention, the radicals are hydrogen atoms H's.

According to yet another aspect of the present invention, the film deposition material is a SOG, and the SOG is coated and deposited on the substrate. By using the SOG, it becomes easy to form a flat insulation film.

According to yet another aspect of the present invention, the SOG includes one or more among a ladder-type hydrogen silsesquioxane, a hydrogen siloxane, and a silicate. In this case, the insulation film becomes a silicon oxide film.

According to yet another aspect of the present invention, the heating process is performed in an atmosphere of N₂ or an inert gas. This causes a dehydration polycondensation reaction.

According to yet another aspect of the present invention, the SOG further includes a silazane. In this case, the insulation film becomes a silicon oxide film.

According to yet another aspect of the present invention, the heating process is performed in an atmosphere of any one among H₂O, O₂, or H₂O₂. In this case, hydrolysis or oxidation causes a polycondensation reaction that eliminates nitrogen.

According to yet another aspect of the present invention, the substrate is a semiconductor substrate or a substrate formed with a semiconductor device pattern. In this case, an insulation film can be formed on a semiconductor substrate or an insulation film can be formed on a semiconductor device pattern.

According to an aspect of the present invention, a circuit device comprising an insulation film formed on a substrate is provided; the circuit device comprises an insulation film of which hydrogen concentration in the film is equal to or less than 1%.

According to the above-mentioned aspect, as the circuit device comprises an insulation film of which hydrogen concentration in the film is equal to or less than 1%, insulation characteristics can be improved.

According to a detailed aspect of the present invention, the above-mentioned circuit device has characteristics of repeating several times a concentration pattern related to hydrogen concentration that is saturated at a substrate side and becomes approximatively zero at a surface side. In this case, it can be provided with a thick insulation film with insulation characteristics totally improved.

### BRIEF DESCRIPTION OF THE DRAWINGS

FIG. 1A is a conceptual diagram that explains an overview of a manufacturing method of an insulation film, and FIG. 1B to FIG. 1E are conceptual cross-sectional views that explain each steps thereof.

FIG. 2A is a conceptual cross-sectional view that explains a substrate as a target to form an insulation film thereon; FIG. 2B is a diagram that explains a forming of a deposition material layer; FIG. 2C is a diagram that explains a heating process; and FIG. 2D is a conceptual cross-sectional view that explains a precursor layer or the like obtained by the heating process.

FIG. 3A is a diagram that explains an exposure process, and FIG. 3B is a conceptual cross-sectional view that explains the insulation film obtained by the exposure process.

FIG. 4A and FIG. 4B are conceptual cross-sectional views that explain manufacturing processes of a laminated-type insulation film.

FIG. 5 is a chart that explains a relationship between plasma output power and a shrinkage rate of a SiO₂ film.

FIG. 6 is a chart that explains an effect of the treatment using radicals formed by high-density plasma.

FIG. 7A and FIG. 7B are charts that explain a shrinking of the SiO₂ film by radical treatment.

FIG. 8 is a diagram that explains cross-sectional characteristics of the laminated-type insulation film.

FIG. 9 is a diagram that explains a measurement result of detailed samples characteristics.

FIG. 10A to FIG. 10C are charts that shows relationships between shrinkage rates and insulation characteristics of deposition material layers at radical treatments.

FIG. 11 is a cross-sectional view that explains an example of a circuit device obtained by a manufacturing method of an insulation film according to an embodiment.

FIG. 12A and FIG. 12B are diagrams that explain variation examples of a radical treatment apparatus using high-density plasma.

### DETAILED DESCRIPTION

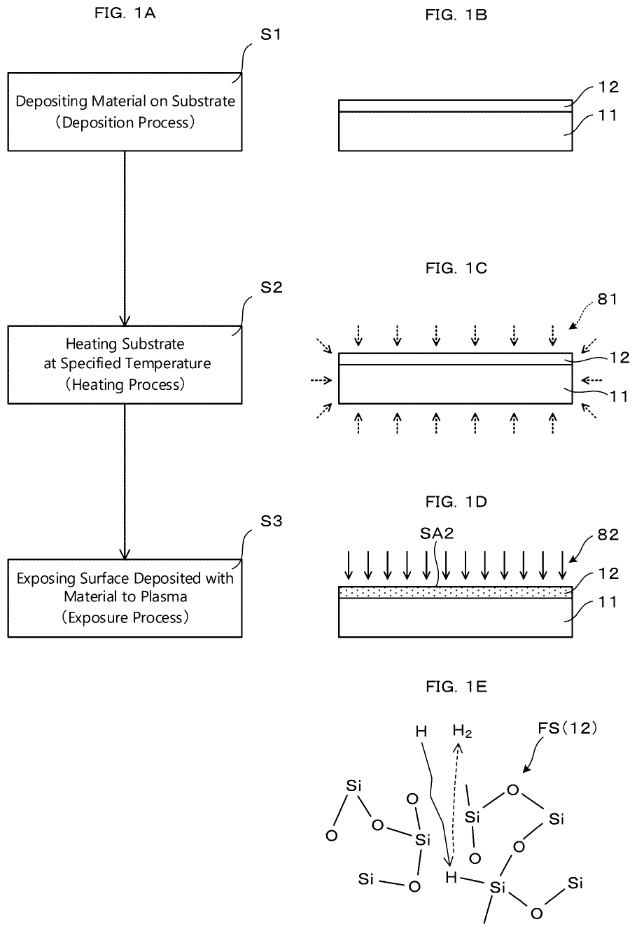

Hereinafter, a manufacturing method of an insulation film and the like according to the present invention will be described in detail with reference to drawings.

[1. A concept of an insulation film manufacturing] FIG. 1 is a conceptual diagram that shows an insulation film manufacturing flow. FIG. 1A is a conceptual diagram that explains a concept of a manufacturing method of an insulation film, and FIG. 1B to FIG. 1D are conceptual diagrams that explain each step (S1 to S3) shown in FIG. 1A. The manufacturing method of the insulation film includes: a deposition process (S1) of depositing a film deposition material on a substrate 11 to form a deposition material layer 12; a heating process (S2) of heating the deposition material layer 12 on the substrate 11 in a heating environment 81 of 85° C. or higher to 450° C. or lower; and an exposure process (S3) of irradiating a surface SA2 of the deposition material layer 12 or a precursor layer on the substrate 11 with plasma 82 containing hydrogen radicals. By the exposure process (S3), in case of manufacturing a silicon oxide film for example, as shown in FIG. 1E, hydrogen H is made to diffuse into a network-like structure FS of the deposition material layer 12 without giving any shock to the structure FS, and is made to bind hydrogen that is a component of the deposition material layer. Hydrogen molecules H₂ thus formed move inside the deposition material layer 12 and are expelled outside the deposition material layer 12. At that time, it is favorable that a product of an irradiation time and a density of the radicals formed by the plasma 82 is equal to or higher than 25×10¹⁴ min·pcs/cm³ from a viewpoint of making the hydrogen H for treatment diffuse deep inside the structure FS of the deposition material layer 12 with an efficient density.

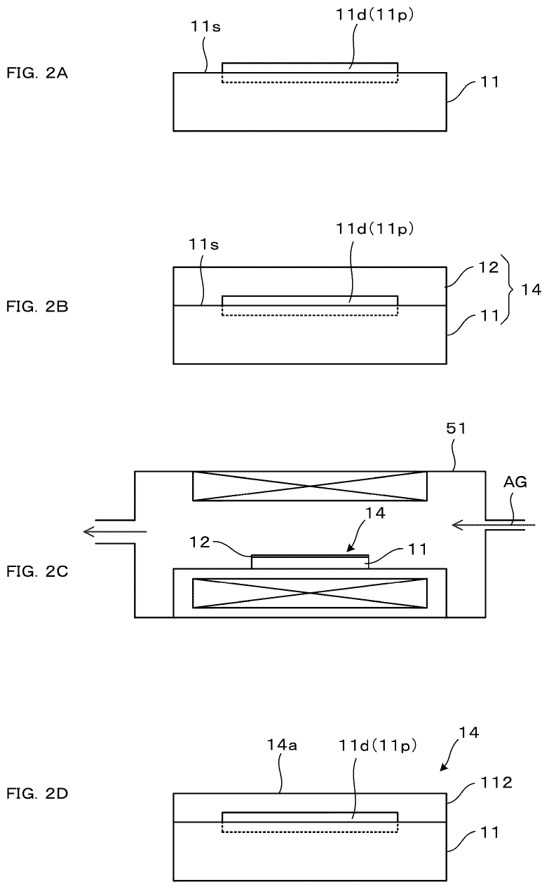

Hereinafter, the manufacturing method of the insulation film according to an embodiment will be described by dividing into the deposition process, the heating process, and the exposure process.

[2. Deposition process] As shown in FIG. 2A, a flat-plate-shaped substrate 11 formed of materials such as semiconductor or other is prepared. The substrate 11 is for example a semiconductor substrate, or may be a substrate with a semiconductor device in which a semiconductor substrate is formed with a pattern lip of a device portion 11d. The substrate 11 is not limited to a semiconductor substrate, may be a ceramic substrate, a glass substrate, a heat-resistant resin substrate, a metal substrate, or the like, and may be formed with a semiconductor device thereon.

Next, as shown in FIG. 2B, a film deposition material is coated on the surface 11s of the substrate 11 to form the deposition material layer 12. The film deposition material is a precursor material of the insulation film such as SiO₂ or a highly fluid material such as inorganic spin on glass (SOG). In case of using a SOG as the film deposition material, the deposition material layer 12 is formed by coating and drying the SOG to form a flat surface on the surface 11s of the substrate 11. As a result, the deposition material layer 12 is deposited on the substrate 11. For example, spin coating method may be used as a method of coating the film deposition material on the substrate 11. The film deposition material coated on the substrate 11 may be prebaked at a relatively low temperature.

The SOG for forming the deposition material layer 12 is for example a solution including one or more among a ladder-type hydrogen silsesquioxane, a hydrogen siloxane, and a silicate as a film component, and is adjusted by adding the above-mentioned film component with organic solvent. The SOG may be for example a solution including a silazane as a film component. The silazane is polymerized into a polymer state.

The ladder-type hydrogen silsesquioxane is shown by the following formula:

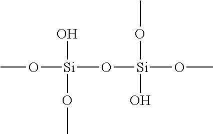

the hydrogen siloxane is shown by the following formula:

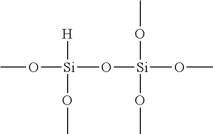

and the silicate is shown by the following formula:

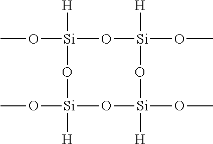

The polymer of the silazane is shown by any one of the following formulae:

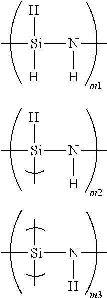

It should be noted that m1, m2, m3 in the above formulae are numbers representing degrees of polymerization.

[3. Heating process] As shown in FIG. 2C, the substrate 11 on which the deposition material layer 12 is deposited is heated under an atmosphere. The temperature to heat the substrate 11 is equal to or higher than 85° C. to equal to or lower than 450° C., favorably equal to or higher than 110° C. to equal to or lower than 200° C. By this heating, the deposition material layer 12 is solidified into a state in which a precursor layer 112 is formed on the substrate 11, as shown in FIG. 2D.

The heating of the substrate 11 on which the deposition material layer 12 is formed, that is, the treatment target 14, is performed for example by baking in a heating furnace 51, and the atmosphere is controlled by supplying an atmosphere gas AG into the heating furnace 51 during the heating. When the deposition material layer 12 is the ladder-type hydrogen silsesquioxane, the hydrogen siloxane, the silicate, or the like, the heating of the treatment target 14 is performed in an atmosphere of N₂ or an inert gas for 10 minutes or more and causes a dehydration polycondensation reaction. When the deposition material layer 12 is the silazane, the heating of the substrate 11 is performed in an atmosphere of any one among H₂O, O₂, or H₂O₂ for 10 minutes or more, and causes a polycondensation reaction that eliminates nitrogen by hydrolysis or oxidation.

A detailed manufacturing example will be described: for example, a treatment target 14 was obtained by performing a spin coating of the polysilazane; the temperature of the substrate thereof was set to 85° C.; water vapor was supplied by bubbling at atmospheric pressure; then the substrate temperature was set to 150° C.; and an annealing was performed in an atmosphere of nitrogen gas at atmospheric pressure for 1 hour.

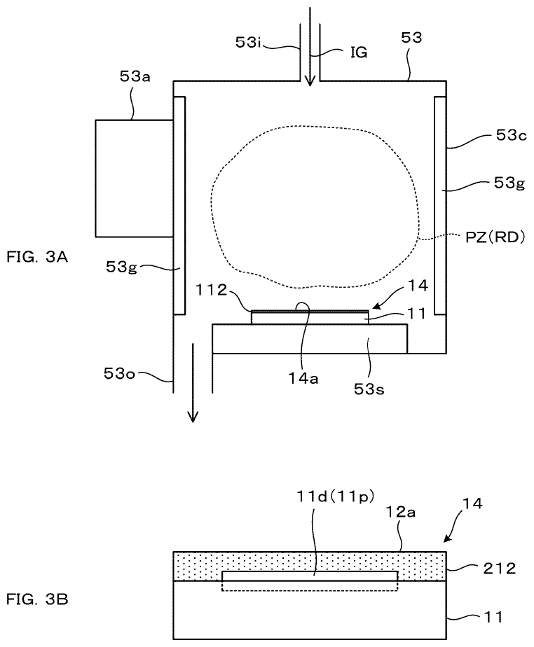

In the above-described heating process, as the temperature of heating the substrate 11 is equal to or higher than 85° C., not only the solvent can be reliably removed, but also activation energy can be given to atoms and molecules of the materials such as the SOG that configures the deposition material layer 12, the polymerization can be proceeded to some extent, and a ratio of Si—O—Si binding can be increased. In addition, as the temperature of heating the substrate 11 is equal to or lower than 450° C., a deterioration of the substrate 11 itself and an occurrence of deterioration in the characteristics of the device portion 11d can be avoided.

[4. Exposure process] As shown in FIG. 3A, the surface 14a of the substrate 11 on which the precursor layer 112 is formed, that is, the treatment target 14, is exposed to plasma. To be more specific, the surface 14a of the treatment target 14 is exposed to a high-density plasma PZ including radicals with a density of 5×10¹⁴ pcs/cm³ or more for example, for 5 minutes to 20 minutes for example. As a result, a product of an irradiation time and the density of the radicals RD in the high-density plasma PZ used for radical treatment of the treatment target 14 becomes equal to or higher than 25×10¹⁴ min·pcs/cm³. At that time, the temperature of the substrate 11 is kept constant in a range from 0° C. to 400° C. In addition, it is favorable that a potential difference between the plasma and the surface of the treatment target 14 is equal to or less than 10V. The irradiation density of the radicals RD may be determined according to a known method (refer to: T. Arai et al. (2016) “Selective Heating of Transition Metal Usings Hydrogen Plasma and Its Application to Formation of Nickel Silicide Electrodes for Silicon Ultralarge-Scale Integration Devices” Journal of Materials Science and Chemical Engineering, 2016, 4, pp. 29-33). It should be noted that although the irradiation density of the radicals RD changes in accordance with a pressure of the plasma, the radical irradiation density in accordance with the plasma pressure and other conditions may be obtained by an experiment in advance.

The radical exposure to the substrate 11 on which the precursor layer 112 is formed, that is, the treatment target 14, is performed by a high-density plasma treatment apparatus 53 provided with a microwave supply source 53a for example; and a radical source gas IG that is introduced from an intake port 53i as an inlet is radicalized by a microwave in a standing wave state inside a chamber 53c. The radical source gas IG is at least one among H₂, NH₃, and H₂O. The radical source gas IG is introduced through the intake port 53i into the chamber 53c, and is exhausted through an exhaust port 53o provided at the bottom of the chamber 53c to outside the chamber 53c. The radicals in the high-density plasma PZ is obtained by being excited by the microwave; the aimed radicals are hydrogen atoms while other components may be included. It should be noted that an inner surface of the chamber 53c is a dielectric tube 53g made of quartz for example; the microwave is injected into this dielectric tube 53g; and a stage 53s that supports the substrate 11 and adjusts the temperature thereof is arranged at the bottom of the dielectric tube 53g. For example, a disclosure of WO 2003/096769 may be used as the high-density plasma treatment apparatus 53. During the plasma exposure, unnecessary gas is exhausted through the exhaust port 53o of the chamber 53c to outside, and a state of the high-density plasma PZ formed inside the dielectric tube 53g is maintained. Inside of the chamber 53c is maintained to 5 Pa to 50 Pa by the high-density plasma PZ. By setting the plasma in the chamber 53c to a plasma density of 5 Pa or higher, it becomes easy to set the potential difference between the plasma and the precursor layer 112 to 10V or lower, and it can prevent plasma particles from being injected into the precursor layer 112, disturbing the structure of the precursor layer 112, and decreasing the density thereof. On the other hand, by setting the plasma in the chamber 53c to a plasma density of 50 Pa or lower, a mean free path of the radicals can be kept relatively long, and the generated radicals can be effectively used to reach the precursor layer 112.

As shown in FIG. 3B, by the process of exposing the treatment target 14 to the high-density plasma PZ by use of the apparatus shown in FIG. 3A, the precursor layer 112 is condensed, and a silicon-based insulating film 212 is formed on the substrate 11. The silicon-based insulation film 212 exposed to the high-density plasma PZ is condensed under an influence of H radicals in the plasma, and the shrinkage rate thereof is 5% to 25% when untreated film thickness is 150 nm. Therefore, a thickness d2 of the silicon-based insulation film 212 is reduced by about 5% to 20% compared to a thickness d1 of the precursor layer 112.

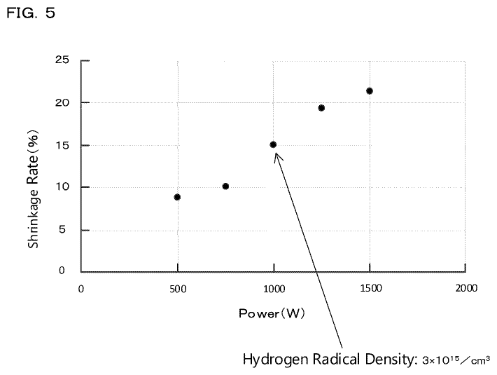

FIG. 5 is a chart that explains a relationship between an output power of the high-density plasma treatment apparatus 53 and the shrinkage rate of the precursor layer 112. The horizontal axis represents a microwave output power of the high-density plasma treatment apparatus 53, and the vertical axis represents the shrinkage rate of the precursor layer 112. In this experiment, a supply rate of H₂ gas into the chamber was set to 10 sccm, a pressure in the chamber was set to 20 Pa, a treatment time by the plasma, that is, the radicals, was set to 5 minutes. The thickness of the untreated (initial) SiO₂ film was 155 nm. When the output power of the microwave that supplies the plasma is set to 1000 W, the radical density is 3×10¹⁵·pcs/cm³. At that time, the shrinkage rate of the precursor layer 112 is 15%. It is understood from this chart that the shrinkage rate of the precursor layer 112 is approximatively proportional to the microwave output power of the high-density plasma treatment apparatus 53. That is, it is understood that if the supply rate of H₂ gas as the radical source gas IG is enough and is not excessive, the density of the plasma, that is, the hydrogen radicals can be increase to have a positive correlation with the output power of the high-density plasma treatment apparatus 53, and the precursor layer 112 can be shrunk in accordance with the density of the hydrogen radicals.

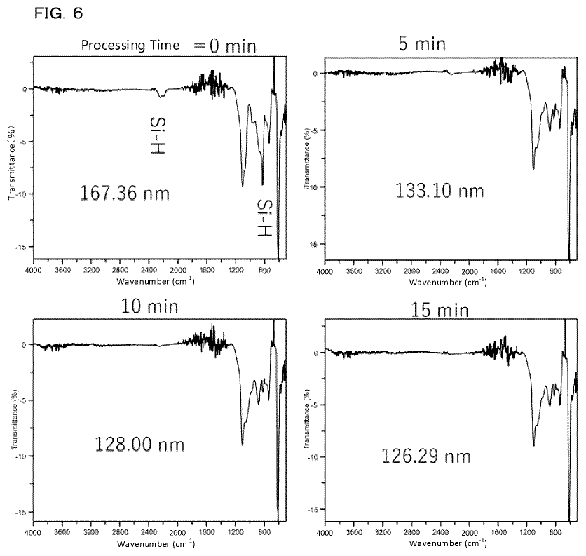

FIG. 6 is a chart that explains a temporal effect of the radical treatment by the high-density plasma PZ. In this case, spectrum of Fourier transform infrared spectroscopy (FTIR) were measured in each of: a comparative sample in which the radical treatment using the plasma has not been performed to the precursor layer 112 (more specifically the silicon oxide layer) after the heating process on the substrate 11 by the process shown in FIG. 3A; and samples in which the radical treatments of 5 minutes, 10 minutes and 15 minutes have been respectively performed to the precursor layer 112 with the rate of H₂ supply into the chamber set to 10 sccm, a pressure inside the chamber set to 20 Pa, and the microwave output power set to 1500 W. In the sample in which a radical treatment of 5 minutes has been performed, almost no Si—H bond was observed already, and in the samples in which a radical treatment of 10 minutes or 15 minutes has been performed, no Si—H bond was observed at all.

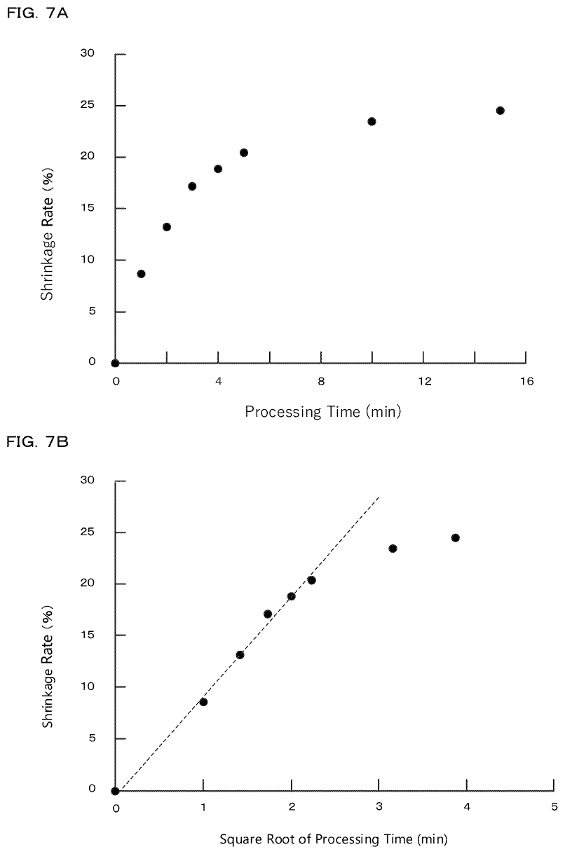

FIG. 7A is a chart that explains a shrinkage of the precursor layer 112 (more specifically, the silicon oxide film) by the radical treatment using the plasma. The horizontal axis represents the radical treatment time, and the vertical axis represents the shrinkage rate of the precursor layer 112. In the above-described radical treatment, the supply rate of the H₂ gas into the chamber was set to 10 sccm, the pressure in the chamber was set to 20 Pa, and the radical treatment time was set to 1, 2, 3, 4, 5, 10, and 15 minutes. The thickness of the untreated (initial) silicon oxide film was 155 nm. Although FIG. 7B shows the shrinkage of the silicon oxide film due to the radical treatment similarly to FIG. 7A, the horizontal axis represents a square root of the radical treatment time. As shown in FIG. 7A, it is understood that when the radical treatment time is equal to or longer than 5 minutes, the shrinkage rate of the insulation film is 20% or more, becoming saturated. As shown in FIG. 7B, the shrinkage rate is increasing proportionally to the square root of the treatment time until around 5 minutes. That is, it can be said that the radical treatment affects in a depth direction proportionally to the square root of the treatment time. This corresponds to a fact that a diffusion length of the hydrogen radicals from the surface of the silicon oxide film is proportional to the supply time of the hydrogen radicals, and it is understood that this phenomenon is dominated by the diffusion. Although the shrinkage rate is saturated after radical treatment time of 5 minutes or longer, considering the FTIR signal described in FIG. 5, this saturation means that the dehydrogenation treatment of the entire SiO₂ film has been completed.

Although a relationship between the treatment time and the shrinkage rate when H₂ supply pressure (that is, plasma supply pressure) is set to 20 Pa has been described in the above, similar result was obtained when the plasma supply pressure is changed in a range of 5 Pa or more to 50 Pa or less. This indicates that the hydrogen radicals rapidly diffuse into the network structure of the SiO₂ film without giving the SiO₂ film with any shock that may make the network structure or the skeleton structure of the SiO₂ film be rearranged.

Returning to FIG. 3A, by exposing the precursor layer 112 on the substrate 11 to the high-density plasma PZ, the hydrogen radicals rapidly diffuse into the precursor layer 112, reduce Si—H bonds and Si—OH bonds, promote condensation of the SiO₂ film, and become the high-density silicon oxide film.

More specifically, in the SiO₂ precursor after heating process, radicals containing hydrogen penetrate from the surface to diffuse toward the substrate 11, reactions such as Si—H+H=Si—+H₂ or Si—OH+H=Si—O—+H₂ that makes hydrogen be released proceed, and Si—O—Si bonds can be increased.

When a material of the precursor layer 112 is the ladder-type hydrogen silsesquioxane, the hydrogen siloxane, the silicate, and the like, the radicals supplied by the high-density plasma PZ diffuse in the surface of precursor layer 112, that is, from the surface 14a to a depth of 600 nm. Therefore, if the thickness of the precursor layer 112 is equal to or less than 600 nm, the entire precursor layer 112 can be high-densified, and a silicon-based insulation film 212 with an extremely high SiO₂ ratio and excellent insulating characteristics can be obtained. When a material of the precursor layer 112 is the silazane, the radicals supplied by the high-density plasma PZ diffuse in the surface of the precursor layer 112, that is, from the surface 14a to a depth of 1.5 μm. Therefore, if the thickness of the precursor layer 112 is equal to or less than 1.5 μm, the entire precursor layer 112 can be high-densified, and a silicon-based insulation film 212 with an extremely high SiO₂ ratio and excellent insulation characteristics can be obtained.

Although it was assumed in the above description that the silicon-based insulation film 212 consists of a single layer, several layers of the silicon-based insulation films 212 may be laminated to obtain a desired silicon-based insulation film. In this case, a silicon oxide film with a desired thickness may be obtained by repeating the deposition process, the heating process, and the exposure process. When a material of the precursor layer 112 is the ladder-type hydrogen silsesquioxane, the hydrogen siloxane, the silicate, and the like, and when it is desired to form a silicon oxide film corresponding to a precursor layer 112 with a thickness of 600 nm or more, several layers of the silicon-based insulation films 212 will be laminated. On the other hand, when a material of the precursor layer 112 is the silazane, by exposing the precursor layer 112 with a thickness of 1.5 μm or less to the radicals, a silicon oxide film that substantially covers usual applications as the silicon-based insulation film 212 will be obtained.

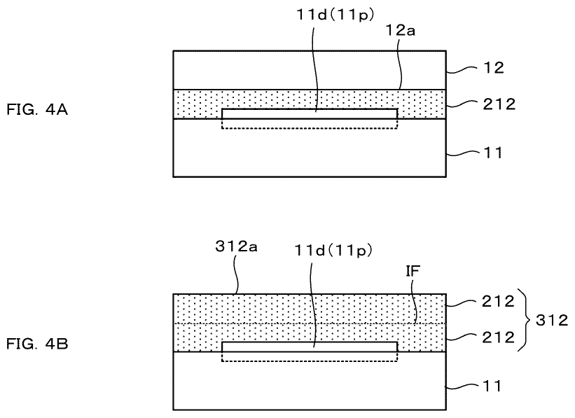

Detailed method of the multi-layer lamination will be described: as shown in FIG. 4A, the film deposition material is coated on the surface 12a of the silicon-based insulation film 212 formed on the substrate 11; and the deposition material layer 12 is formed. Then, by the heating process shown in FIG. 2C, similarly to the case in FIG. 2D, the deposition material layer 12 on the silicon-based insulation film 212 is made to be the precursor layer 112; by the exposure process shown in FIG. 3A, a precursor layer 112 on a first silicon-based insulation film 212 is made to be a second silicon-based insulation film 212; and a laminated-type silicon-based insulation film 312 as shown in FIG. 4B is obtained.

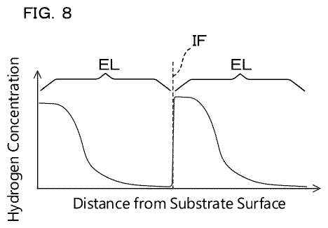

FIG. 8 is a diagram that explains a hydrogen concentration distribution in a laminated-type silicon-based insulation film. The horizontal axis represents a distance from a surface 11s of the substrate 11 as a base to a surface of the silicon-based insulation film 312, and the vertical axis represents the hydrogen concentration in the silicon-based insulation film 312. In case of the laminated-type silicon-based insulation film 312, a distribution of the hydrogen concentration is repeated in units of constitution layer EL. In each constitution layer EL, the hydrogen concentration is saturated at a maximal value at a position near the substrate 11, and the hydrogen concentration is reduced to a value around zero inside the interface IF and at a position near the surface of the silicon-based insulation film 312. At the interface IF between constitution layers EL, the hydrogen concentration rapidly changes. That is, a laminated-type silicon-based insulation film 312 has characteristics related to the hydrogen concentration in that a concentration pattern of being saturated at the substrate 11 side and becoming around zero at the surface 312a side is repeated several times. At a forming of each constitution layer EL that constitutes a laminated-type silicon-based insulation film 312, the hydrogen radicals from the high-density plasma PZ efficiently diffuse into the constitution layers EL through the surface of each constitution layer EL to bind with hydrogen, and this makes Si—O bonds to increase while Si—H bonds are made to decrease; therefore the hydrogen concentration can be lowered except the bottom of each constitution layer EL, insulation characteristics of the constitution layers EL can be improved, and the plurality of constitution layer EL as a whole can exhibit insulation characteristics.

[5. Manufactured silicon-based insulation film] The silicon-based insulation films 212, 312 formed on the substrate 11 by the above-described process are silicon oxide films. The leakage current thereof is equal to or lower than 1×10⁻⁸ A/cm². The dielectric breakdown electric field thereof is equal to or higher than 8 MV/cm to equal to or lower than 10 MV/cm. In addition, this silicon oxide film has a density equal to or higher than 2.50 g/cm³ to equal to or lower than 2.65 g/cm³, and the ratio of Si—OH bonds and Si—H bonds included therein is equal to or lower than 1%.

In addition, the silicon-based insulation film 212 manufactured by the manufacturing method of the present invention has a thickness of 100 nm or more, and at this film thickness that was not easy to manufacture by conventional manufacturing method, a low leakage current is achieved and the dielectric breakdown electric field strength is increased.

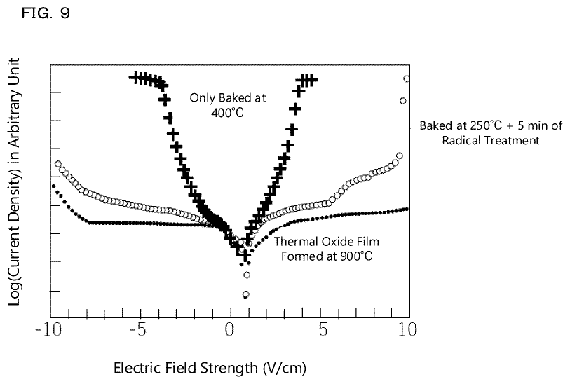

FIG. 9 is a chart that explains a result of measuring characteristics of samples of silicon oxide films that are specific silicon-based insulation films 212. The horizontal axis represents the voltage applied to the silicon oxide film and the vertical axis represents leakage current of the silicon oxide film. White circle marks represent leakage current of the sample obtained by setting the output power of the microwave supply source 53a to 1 kW, reducing the pressure of the chamber 53c with a capacity of 0.05 cubic meters, setting the flow rate of H₂ to 5 sccm (scc/minute), and setting the inside pressure to 20 Pa. It is understood that in these samples, the leakage current is suppressed to about 1×10⁻⁸ A/cm² and the dielectric breakdown electric field is about 9 MV/cm. It should be noted that black disk marks represent results obtained with a sample of a conventional silicon oxide film in which the deposition material layer 12 is treated with a high temperature of 900° C. to which radical treatment by plasma is not performed; and “+” marks represent results obtained with a sample of a conventional silicon oxide film in which the deposition material layer 12 is treated at 400° C. to which radical treatment is not performed. It is understood that insulation characteristics obtained with the sample represented by the white circle marks are approaching those being treated at a high temperature of 900° C.

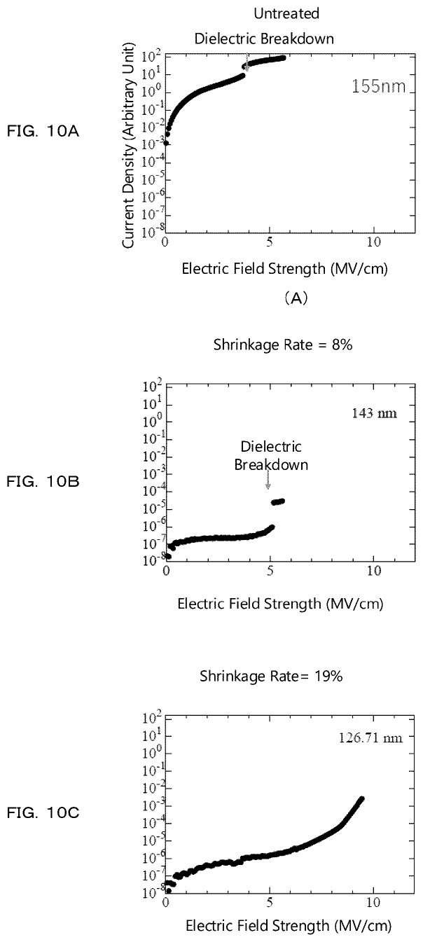

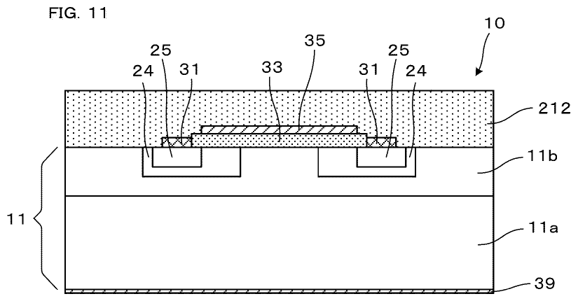

FIG. 10A to FIG. 10C are charts that show relationships between shrinkage rate and insulation characteristics of the precursor layer 112 during the radical treatment measured for the silicon oxide film as a specific silicon-based insulation film 212. FIG. 10A shows insulation characteristics of a comparative example to which no radical treatment has been performed; FIG. 10B shows insulation characteristics of an embodiment example in which the precursor layer 112 has shrunk by 8% by the radical treatment; and FIG. 10C shows insulation characteristics of an embodiment example in which the precursor film 112 has shrunk by 19% by the radical treatment. In case of the shrinkage rate of 8% shown in FIG. 10B, the resistance is large, and the current density is suppressed to be low, while a dielectric breakdown occurs at 5 MV/cm. In case of the shrinkage rate of 19% shown in FIG. 10C, the resistance is large, the current density is suppressed to be low, and no dielectric breakdown occurs even with an electric field strength close to 10 MV/cm.

[6. Semiconductor device provided with insulation film] FIG. 11 is a cross sectional view that explains an example of a semiconductor device 10 that is a circuit device obtained by the above-described manufacturing method of insulation film. The semiconductor device 10 is a MOSFET that is a kind of power device. In this case: the substrate 11 is SiC for example; a back surface side of the substrate 11 is a drain layer 11a of n*SiC; a drain electrode 39 is formed on the back surface; a front surface side of the substrate 11 is a drift layer 11b of n-SiC; and a pair of body regions 24 of pSiC and a pair of source regions 25 of n*SiC are formed to be embedded in the drift layer 11b. Agate oxide film (insulation film) 33 is formed to cover a local region of the drift layer 11b in which the local region is sandwiched between the pair of source regions 25, and a gate electrode 35 is formed thereon. Wirings 31 are connected to the pair of source regions 25. The body regions 24, the source regions 25, the gate oxide film 33, the gate electrode 35, and the like correspond to the device portion 11d shown in FIG. 2A and are covered by the silicon-based insulation film 212. It should be noted that, although not shown, an insulation layer may be formed between the wirings 31 and the surface of the substrate 11 in advance.

In the manufacturing method of insulation film according to the present embodiment: a process of depositing the deposition material layer 12 on the substrate 11, a process of heating the substrate 11 at a temperature equal to or higher than 85° C. to equal to or lower than 450° C., and a process of exposing the surface of the precursor layer 112 formed on the substrate 11 to the high-density plasma PZ containing hydrogen radicals are included; the hydrogen radicals formed by the high-density plasma PZ has a density equal to or higher than 5×10¹⁴ pcs/cm³; and a product of the irradiation time and the density of the hydrogen radicals is equal to or higher than 25×10¹⁴ min·pcs/cm³. By this method, as no heating at high temperature is performed, the insulation characteristics of the silicon-based insulation film 212 can be improved without deteriorating characteristics of the substrate 11 before forming the silicon-based insulation film 212 or the device portion 11d formed thereon.

[7. Others] Although the present invention has been described in the above with reference to the embodiments, the present invention is not limited to the above embodiments and can be implemented in various aspect within a range of not departing from the scope thereof. For example, the target to incorporate the insulation film may be not only the MOSFET shown in FIG. 5 but also an IGBT or other power devices, may be also various types of LSI other than power devices, and may be an element that constitutes each section of a display.

The insulation film is not limited to be used as an interlayer insulation film and may be for example a functional layer such as a gate insulation film that constitutes a circuit device. For example, the insulation film or the silicon-based insulation film of the present application can be used as an insulation film adjacent to a floating gate that constitutes a flash memory. When incorporated as an integrated circuit, the insulation film can be incorporated as an insulation film that constitute each circuit element and an insulation film that separates device elements, and can have a functional multilayer structure that insulates necessary portions inside and outside an element in a laminated body of many circuit elements.

The film deposition material that forms the deposition material layer 12 is not limited to inorganic silicon compound such as above-described hydrogen silsesquioxane, and may be an organic silicon compound such as an organic SOG. Furthermore, a silicon oxide film having excellent insulation characteristics can be obtained by performing an exposure process as described above to a film deposition material formed by use of tetraethoxysilane (TEOS) by CVD or the like, and a film deposition material formed by use of silane (SiH₄) by CVD or the like. In this case, the deposition process and the heating process are performed at once. That is, the substrate is placed on a substrate stage kept at a temperature equal to or higher than 150° C. to equal to or lower than 400° C. to deposit a SiO₂ film.

The insulation film is not limited to SiO₂ film, and may be silicon nitride (Si₃N₄). Silicon Nitride is formed by plasma CVD for example. Reaction formulae thereof are as shown below, and treatment temperature is about 600° C. for example.

3SiH₄+4NH₃→Si₃N₄+12H₂

3SiCl₂H₂+4NH₃→Si₃N₄+6HCl+6H₂

In this case also, by exposing a silicon nitride precursor layer 112 to the high-density plasma PZ containing radicals of which density is equal to or higher than 5×10¹⁴/cm³ for example, more preferably, by performing the radical treatment so that the product of the irradiation time and the density of the radicals formed by the high-density plasma PZ is equal to or higher than 25×10¹⁴ min·pcs/cm³, the precursor layer 112 can be made to condense, and a silicon nitride film is formed on the substrate 11. Herein, a high-density plasma PZ containing H radicals is used to lower the hydrogen concentration. The silicon nitride film obtained from the precursor layer 112 exposed to the high-density plasma PZ is condensed under influence of the radicals and the insulation characteristics thereof is improved.

The insulation film is not limited to SiO₂ film and may be aluminum oxide (Al₂O₃). In this case also, by exposing a precursor layer 112 of aluminum oxide to a high-density plasma PZ containing H radicals of which density is equal to or higher than 5×10¹⁴/cm³ for example, more preferably by performing the radical treatment so that a product of the irradiation time and the density of the radicals formed by the high-density plasma PZ is equal to or higher than 25×10¹⁴ min·pcs/cm³, the precursor layer 112 can be made to condense, and an aluminum oxide film is formed on the substrate 11. Herein, a high-density plasma PZ containing H radicals is used to lower the hydrogen concentration. The aluminum oxide film exposed to the high-density plasma PZ is condensed under influence of the radicals and the insulation characteristics thereof is improved.

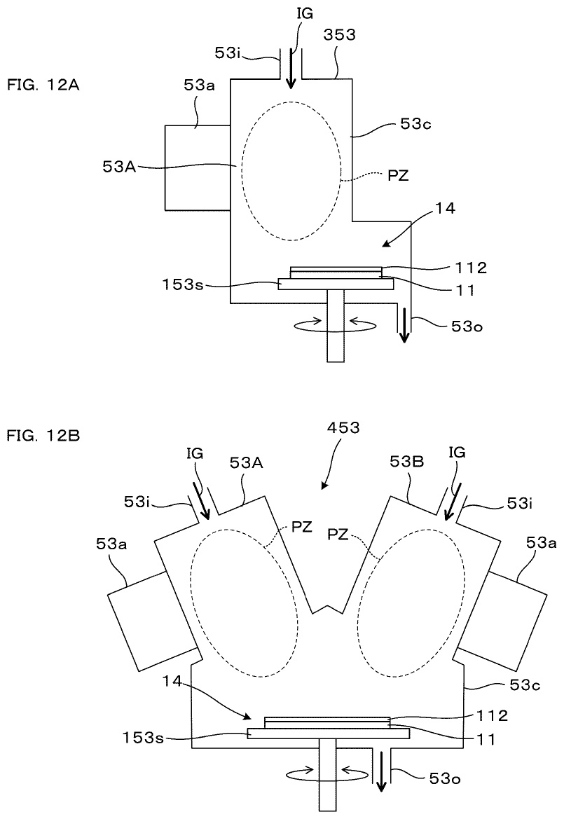

The high-density plasma treatment apparatus 53 is not limited to the one shown in the drawings and various modifications can be made. For example, in the high-density plasma treatment apparatus 353 shown in FIG. 12A, the treatment target 14 is supported on a rotating stage 153s and rotates at a predetermined speed. On the other hand, the high-density plasma treatment section 53A is arranged at a position shifted from directly above the rotating stage 153s. In this case, even if a density distribution of the high-density plasma PZ or the radicals in each part of the rotating stage 153s occurs, the radicals can be uniformly supplied and irradiated on the entire surface of the precursor layer 112, by a rotation of the treatment target 14.

The high-density plasma treatment apparatus 453 shown in FIG. 12B has a structure in which two high-density plasma treatment apparatuses 53A, 53B are combined. In this case also, by the rotation of the treatment target 14 supported on the rotating stage 153s, the radicals can be uniformly supplied and irradiated on the entire surface of the precursor layer 112.

The method of coating the film deposition material on the substrate 11 is not limited to the spin coating method and may use a brush or a roller.

1. A manufacturing method of an insulating film, the method including a deposition process, a heating process, and an exposure process,
wherein the deposition process includes depositing a film deposition material on a substrate to form a deposition material layer,
wherein the heating process includes heating the deposition material layer on the substrate at a temperature equal to or higher than 85° C. to equal to or lower than 450° C.,
wherein the exposure process includes irradiating a surface of the deposition material layer on the substrate with a plasma containing hydrogen radicals to make hydrogen diffuse into a structure of the deposition material layer and bind the hydrogen to a component of the deposition material layer, and
wherein a product of an irradiation time and a density of radicals formed by the plasma is equal to or higher than 25×10¹⁴ min·pcs/cm³.

2. The manufacturing method of the insulation film according to claim 1,
wherein the radicals are provided to the surface of the deposition material layer by a forming of the plasma under a pressure equal to or higher than 5 Pa to equal to or lower than 50 Pa.

3. The manufacturing method of the insulation film according to claim 1,
wherein the radicals are hydrogen atoms H's.

4. The manufacturing method of the insulation film according to claim 1,
wherein the film deposition material is a spin on glass (SOG), and
wherein the SOG is coated and deposited on the substrate.

5. The manufacturing method of the insulation film according to claim 4,
wherein the SOG includes one or more among a ladder-type hydrogen silsesquioxane, a hydrogen siloxane, and a silicate.

6. The manufacturing method of the insulation film according to claim 5,
wherein the heating process is performed in an atmosphere of N₂ or an inert gas.

7. The manufacturing method of the insulation film according to claim 6,
wherein the SOG further includes a silazane.

8. The manufacturing method of the insulation film according to claim 7,
wherein the heating process is performed in an atmosphere of one among H₂O, O₂, or H₂O₂.

9. The manufacturing method of the insulation film according to claim 1,
wherein the substrate is a semiconductor substrate or a substrate formed with a semiconductor device pattern.
